(19) United States
(12) Patent Application Publication
(10) Pub. No.: US 2007/0200246 A1
(43) Pub. Date: Aug. 30, 2007

(54) Chip package

(76) Inventors: Ming-Liang Huang, Tainan County (TW); Chia-I Tsai, Tainan County (TW)

Correspondence Address: J.C. Patents, Inc., Suite 250, 4 Venture, Irvine, CA, 92618, US

(21) Appl. No.: 11/416,357

(22) Filed: May 1, 2006

(30) Foreign Application Priority Data
Feb. 24, 2006 (TW) 95106254

(51) Int. Cl. H01L 23/48

(52) U.S. Cl. 257/774

(57) ABSTRACT

A chip package including a flexible substrate, a plurality of conductive plugs, a wiring layer, and a chip is provided. The flexible substrate has a first surface and a second surface opposite to the first surface. The conductive plugs pass through the flexible substrate. The wiring layer is located on the first surface and has a plurality of inner leads electrically connected to the conductive plugs respectively. The chip has an active surface and a plurality of bumps on the active surface, wherein the chip is disposed on the second surface of the flexible substrate and connected with the conductive plugs by the bumps. As bumps on the chip are electrically connected to the conductive plugs by hot pressing, the chip is quickly and reliably electrically connected to the inner leads.

### CROSS-REFERENCE TO RELATED APPLICATION

This application claims the priority benefit of Taiwan application serial no. 95106254, filed on Feb. 24, 2006. All disclosure of the Taiwan application is incorporated herein by reference.

### BACKGROUND OF THE INVENTION

1. Field of the Invention

The present invention relates to a chip package, and more particularly, to a chip package using a flexible substrate.

2. Description of Related Art

In current package techniques, a chip is electrically connected with a chip carrier mainly through wire bonding, flip chip, or tape automated bonding (TAB). Among the bonding techniques, since TAB has the advantages of, for example, implementing an electrical test directly on a flexible substrate, completing a 3-dimensional assembly of electronic devices by utilizing the flexible substrate, and fabricating a thin and small chip package, etc., chip packages made by TAB have been widely applied in electronic products such as personal computers, liquid crystal televisions, hearing aids, and memory cards.

FIG. 1 is a schematic sectional view of a conventional chip package. Referring to FIG. 1, a chip package 100 includes a flexible substrate 110, a wiring layer 120, a chip 130, a plurality of bumps 140, and an encapsulant 150. The flexible substrate 110 is comprised of polyimide. The wiring layer 120 is disposed on a surface 112 of the flexible substrate 110. The wiring layer 120 has a plurality of inner leads 122, a plurality of traces 124, and a plurality of outer leads 126, wherein the inner leads 122 are electrically connected with the corresponding outer leads 126 via the traces 124, respectively.

The chip 130 is disposed on the wiring layer 120, and is electrically connected with the inner leads 122 via the bumps 140. Generally, in the conventional art, a pressure head 160 of a hot press is pressed on a surface 114 opposite to the surface 112 of the flexible substrate 110, and the chip 130 is electrically connected to the inner leads 122 via the bumps 140 through the pressure and heat applied to the flexible substrate 110 by the pressure head 160. The encapsulant 150 is disposed on the surface 112. The encapsulant 150 is disposed on the periphery of the chip 130 and encapsulates the bumps 140. In addition, the encapsulant 150 is further filled in a gap between the flexible substrate 110 and the chip 130.

It should be noted that when the pressure head 160 applies heat to the flexible substrate 110, the heat is mainly delivered to the bumps 140 via the flexible substrate 110 and the wiring layer 120. However, since the material of the flexible substrate 110 is polyimide which has a considerably high thermal resistance, under the condition that the flexible substrate 110 is not damaged, it will take a long time to raise the temperature of the bumps 140 suitable for hot pressing in the conventional art, therefore the production efficiency of the chip package 100 is low.

Furthermore, the flexible substrate 110 with a high thermal resistance tends to cause non-uniformity of the heat delivered to the bumps 140 by the pressure head 160, such that the bumps 140 are heated to different temperatures at the same time. Thus, a part of the bumps 140 are easily bonded with the inner leads 122 under an inappropriate temperature, thereby causing a flaw in the quality of the electrical connection between the wiring layer 120 and the chip 130.

Furthermore, the inner leads 122 and the traces 124 on the surface 112 of the chip package 100 may also cause the encapsulant 150 not fully fill the gap between the flexible substrate 110 and the chip 130. Referring to FIG. 2, a schematic view of the case that the encapsulant in FIG. 1 is not fully filled in the gap between the flexible substrate and the chip is shown, wherein the chip 130 is vitrificated and the profile thereof is represented by dashed lines for convenience of illustration. In the process of forming the encapsulant 150, when flowing into the gap between the flexible substrate 110 and the chip 130, the liquid compound suffers a great flow resistance since a plurality of inner leads 122 and a plurality of traces 124 are disposed on the surface 112. Thus, a void A may be formed in the encapsulant 150.

FIG. 3 is a schematic sectional view of another conventional chip package. The chip package 200 includes a flexible substrate 210, a wiring layer 220, a wiring substrate 230, a plurality of conductive plugs 240, a chip 250, a plurality of bumps 260, and an encapsulant 270. The flexible substrate 210 may be comprised of polyimide. The flexible substrate has a surface 212 and a surface 214 opposite to the surface 210. The wiring layer 220 is disposed on the surface 212, and has a plurality of outer leads 222 and a plurality of traces 224. The wiring layer 230 is disposed on the surface 214, and has a plurality of inner leads 232 and a plurality of traces 234. The conductive plugs 240 pass through the flexible substrate 210, respectively, and electrically connect the wiring layer 220 to the wiring layer 230. Thus, the inner leads 232 may be electrically connected to the outer leads 222 via the traces 234, the conductive plugs 240, and the traces 224. The chip 250 is electrically connected to the inner leads 232 via the bumps 260. The encapsulant 270 is disposed on the surface 214, wherein the encapsulant 270 is disposed on the periphery of the chip 130 and encapsulates the bumps 140. In addition, the encapsulant 270 is further filled in the gap between the flexible substrate 210 and the chip 250.

As mentioned above, since the material of the flexible substrate 210 is polyimide, under the condition that the flexible substrate 210 is not damaged, it takes a long time to raise the temperature of the bumps 260 to that suitable for hot pressing in the conventional art. Therefore the production efficiency of the chip package 200 is low. Moreover, since the flexible substrate 210 with a high thermal resistance also tends to cause non-uniformity of the heat delivered to the bumps 260 by the pressure head 160, therefore a flaw in the quality of the electrical connection between the inner leads 232 and the chip 250 may be formed.

Further, since a plurality of inner leads 232 and a plurality of traces 234 are disposed on the surface 214, when being formed, the encapsulant 270 may not fully fill the gap between the flexible substrate 210 and the chip 250, thereby forming a void A similar to that in FIG. 2 between the flexible substrate 210 and the chip 250 after the liquid encapsulant 270 is cured.

### SUMMARY OF THE INVENTION

Accordingly, an object of the present invention is to provide a chip package, wherein a reliable electrical connection between the chip and the inner lead may be ensured.

Another object of the present invention is to provide a chip package, wherein the encapsulant may be fully filled in the gap between the flexible substrate and the chip.

The present invention provides a chip package including a flexible substrate, a plurality of conductive plugs, a wiring layer, and a chip. The flexible substrate has a first surface and a second surface opposite to the first surface. The conductive plugs pass through the flexible substrate. The wiring layer is located on the first surface. The wiring layer has a plurality of inner leads electrically connected with the conductive plugs, respectively. The chip has an active surface and a plurality of bumps disposed on the active surface, wherein the chip is disposed on the second surface of the flexible substrate, and is bonded to the conductive plugs through the bumps.

The present invention also provides a chip package including a flexible substrate, a plurality of conductive plugs, a wiring layer, and a chip. The flexible substrate has a first surface and a second surface opposite to the first surface. The conductive plugs pass through the flexible substrate. The wiring layer is located on the first surface, and is electrically connected to the conductive plugs. The chip has an active surface and a plurality of bumps disposed on the active surface. The chip is disposed on the second surface of the flexible substrate, and is electrically connected with the conductive plugs through the bumps. The bumps overlap with the conductive plugs, respectively.

According to an embodiment of the present invention, the bumps fully or partially overlap the conductive plugs, respectively.

According to an embodiment of the present invention, the wiring layer further includes a plurality of traces and a plurality of outer leads, and the traces are connected between the inner leads and the outer leads.

According to an embodiment of the present invention, an anisotropic conductive paste (ACP) or an anisotropic conductive film (ACF) may be further disposed between the flexible substrate and the chip, such that the bumps are electrically connected with the conductive plugs.

According to an embodiment of the present invention, a B stage adhesive may be disposed between the flexible substrate and the chip, such that the bumps are electrically connected with the conductive plugs.

According to an embodiment of the present invention, the bumps comprise B stage conductive bumps.

According to an embodiment of the present invention, a conductive paste or metal may be disposed between the bumps and the conductive plugs, such that the bumps and the conductive plugs are electrically connected through the conductive paste or metal.

According to an embodiment of the present invention, a nonconductive polymer may be disposed between the flexible substrate and the chip, such that the bumps are electrically connected to the conductive plugs through curing of the nonconductive polymer.

According to an embodiment of the present invention, an underfill may be disposed between the flexible substrate and the chip so as to encapsulate the bumps.

According to an embodiment of the present invention, the conductive plugs further protrude from the second surface.

According to an embodiment of the present invention, an encapsulant may be disposed on the second surface so as to encapsulate the chip. Additionally, the encapsulant may further have an opening for exposing the back surface of the chip opposite to the active surface.

According to an embodiment of the present invention, the material of the flexible substrate is polymer such as, for example, polyimide.

Since the chip and the inner leads of the present invention are located respectively on the two opposite sides of the flexible substrate, and since the conductive plugs are electrically connected with the bumps directly, when the chip is electrically connected to the conductive plugs through the bumps by hot pressing in the present invention, the temperature of the bumps may be raised suitable for hot pressing more quickly. Therefore the flexible substrate may not get damaged, the chip may be electrically connected to the inner leads quickly and firmly. Further, since only a plurality of bumps exists between the chip and the flexible substrate of the present invention, when being formed, the liquid encapsulant may fully fill the gap between the chip and the flexible substrate.

In order to the make aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 is a schematic sectional view of a conventional chip package.

FIG. 2 is a sectional view of a case that the encapsulant in FIG. 1 is not fully filled in the gap between the flexible substrate and the chip.

FIG. 3 is a schematic sectional view of another conventional chip package.

FIG. 4 is a schematic sectional view of a chip package according to an embodiment of the present invention.

FIG. 5 is a schematic sectional view of a chip package according to another embodiment of the present invention.

FIG. 6 is a schematic sectional view of a chip package according to yet another embodiment of the present invention.

FIG. 7 is a schematic sectional view of a chip package according to yet another embodiment of the present invention.

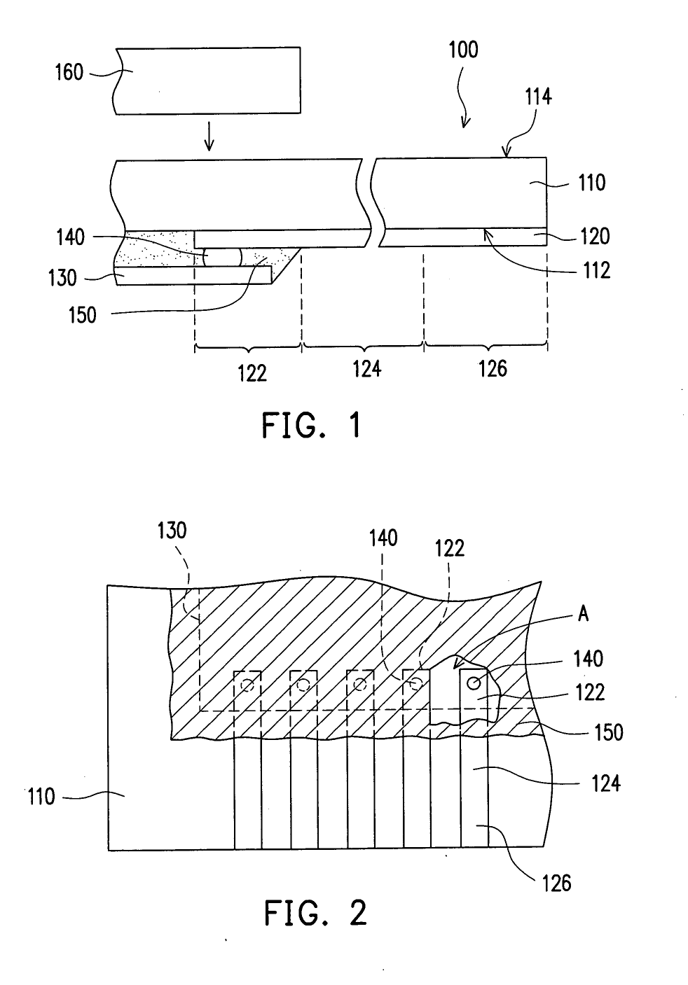

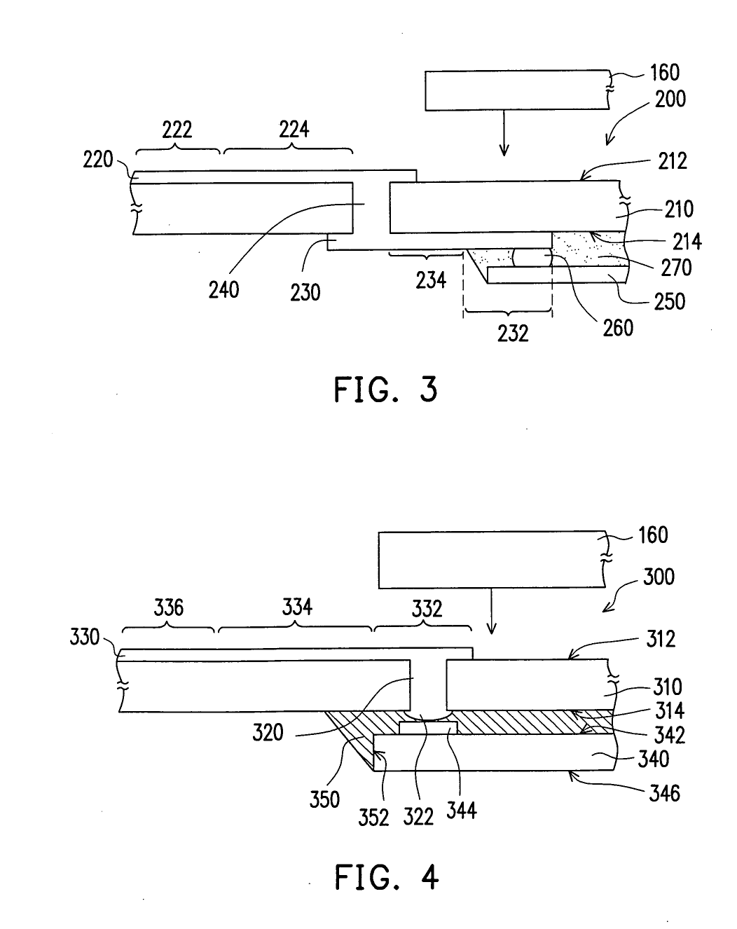

### DESCRIPTION OF EMBODIMENTS

FIG. 4 is a schematic sectional view of a chip package of an embodiment of the present invention. Referring to FIG. 4, the chip package 300 includes a flexible substrate 310, a plurality of conductive plugs 320, a wiring layer 330, and a chip 340. The flexible substrate 310 has a first surface 312 and a second surface 314 opposite to the first surface 310. The material of the flexible substrate 310 is, for example, polyimide or any other suitable flexible polymer. The conductive plugs 320 pass through the flexible substrate 310, and the material of the conductive plugs 320 is, for example, metal. According to an embodiment, the conductive plugs 320 have a semicircular tab 322 protruding from the second surface 314.

The wiring layer 330 formed of metal material is disposed on the first surface 312, and includes a plurality of inner leads 332, a plurality of traces 334, and a plurality of outer leads 336. The conductive plugs 320 are electrically connected with the inner leads 332, respectively, while the outer leads 336 are adapted to be electrically connected with other circuit devices via suitable external connecting terminals.

The chip 340 has an active surface 342, and further has a plurality of bumps 344 on the active surface 342, wherein the bumps 344 comprise, for example, gold bumps, B stage conductive bumps, or any other suitable conductive bumps. The bumps 344 are electrically connected to the conductive plugs 320 respectively, such that the chip 340 may be electrically connected to the circuit devices outside the chip package 300 through the bumps 344, the conductive plugs 320, the inner leads 332, the traces 334, and the outer leads 336.

The method of electrically connecting the chip 340 to the conductive plugs 320 in the embodiment includes pressing the pressure head 160 of the hot press on the inner leads 332 at first. The chip 340 is electrically connected to the conductive plugs 320 through the pressure and heat applied to the inner leads 332 by the pressure head 160. More particularly, since both the inner leads 332 and the conductive plugs 320 are formed of metal materials, and the bumps directly fully overlap the conductive plugs or partially overlap the conductive plugs, the heat output from the pressure head 160 may be conducted more quickly and directly to the bumps 344 through the inner leads 334 and the conductive plugs 320. Thus, the temperature of the conductive plugs 320 and the bumps 344 may be raised quickly to a desirable temperature level suitable for hot pressing, thereby ensuring reliable electrical connection between the conductive plugs 320 and the bumps 344.

Additionally, the chip package 300 further includes an encapsulant 350, wherein the material of the encapsulant 350 includes resin or any other suitable type of protective resin. The encapsulant 350 is disposed on the second surface 314 and surrounds the periphery of the chip 340. In addition, the encapsulant 350 is further filled in the gap between the chip 340 and the flexible substrate 310. The encapsulant 350 has an opening 352, wherein the opening 352 exposes a back surface 346 of the chip 340 opposite to the active surface 342. Thus, a part of the heat output by the chip 340 may make a heat exchange with external environment via the opening 352. The method of forming the encapsulant 350 in the embodiment includes disposing the liquid encapsulant 350 on the periphery of the chip 340 with a dispensing tool, such that the encapsulant 350 is filled in the gap between the chip 340 and the flexible substrate 310. Thereafter, the liquid encapsulant 350 is cured, and a solid encapsulant 350 is obtained. It should be noted that since the wiring layer 330 of the embodiment is formed on the first surface 312, and neither traces nor leads exist on the second surface 314 as in the case of the conventional art, the flow of the encapsulant 350 within the gap between the chip 340 and the flexible substrate 310 may not be blocked by the traces or leads. Therefore the encapsulant 350 meets with negligible flow resistance.

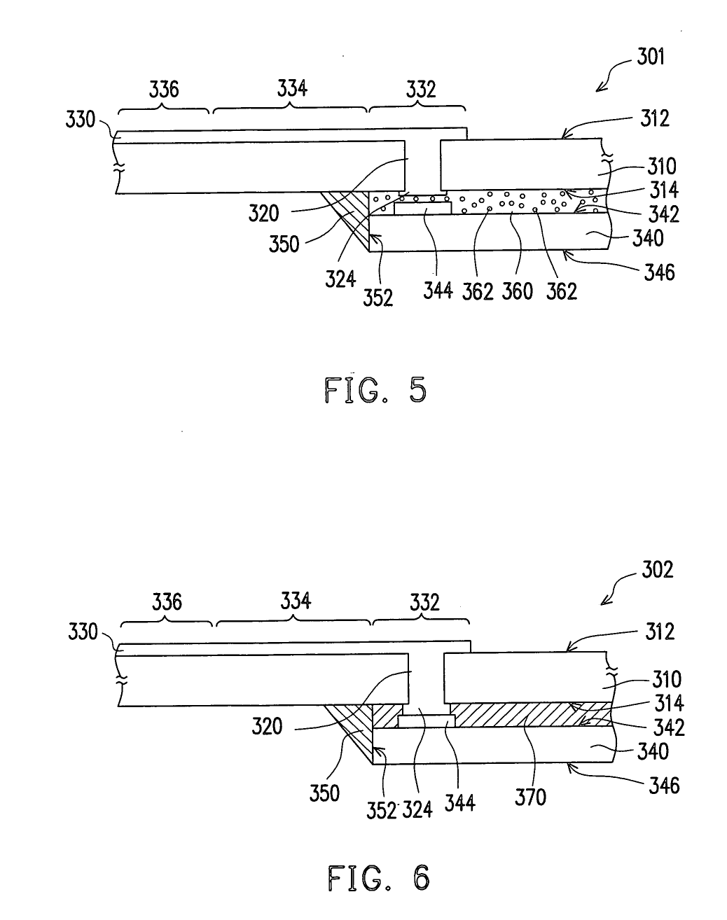

FIG. 5 is a schematic sectional view of the chip package according to another embodiment of the present invention. Referring to FIGS. 4 and 5, a primary difference between the chip package 301 and the chip package 300 lies in that the tab of the conductive plugs 320 protruding from the second surface 314 of the chip package 301 is a pad 324. In particular, the main scope of the present invention lies in the full or partial overlapping between the conductive plugs and the bumps, thus the tab of the conductive plugs 320 protruding from the second surface 314 in the above embodiments may be a semicircular tab 322, a pad 324, or protruding structures with other profiles. In the case that a full or partial overlapping exists between the conductive plugs 320 and the bumps 344 which are electrically connected with each other, the conductive plugs 320 may not protrude from the second surface 314.

Additionally, the chip package 301 may further include a layer of ACP or ACF 360, such that the bumps 344 may be electrically connected with the pad 324 through conducting particles 362 within the ACP 360.

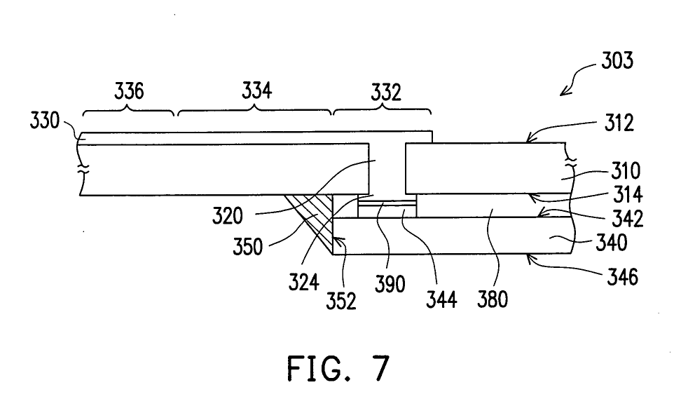

Of course, besides a layer of ACP, a layer of nonconductive polymer or a layer of underfill may be further disposed between the chip and the flexible substrate in the chip package as shown in the schematic views in FIGS. 6 and 7, respectively. Referring to FIG. 6, a main difference between the chip package 302 and the chip package 301 lies in that a layer of nonconductive polymer 370 is disposed between the chip 340 and the flexible substrate 310 of the chip package 302. Thus, a more compact bond is achieved between the pads 324 and the bumps 344 by utilizing the characteristic that a contraction appears in the volume resulting from heating and curing the nonconductive polymer 370 in the embodiment.

Referring to FIG. 7, a main difference between the chip package 303 and the chip package 301 lies in that, a layer of underfill 380 is disposed between the chip 340 and the flexible substrate 310 of the chip package 303, wherein the underfill 380 encapsulates the bumps. Thus, the underfill 380 may act as a buffer between the chip 340 and the flexible substrate 310, thereby avoiding damage in the electrical connection relationship between the chip 340 and the flexible substrate 310 due to a thermal stress. Additionally, a layer of conductive paste or metal 390 may be further disposed between the pads 324 and the bumps 344, such that the pads 324 are electrically connected with the bumps 344 through the conductive paste 390. Of course, the above embodiments are not intended to limit the present invention, and a layer of B stage adhesive or other types of interposer may be further disposed between the chip 340 and the flexible substrate 310.

Since the chip and the inner leads are located on the two opposite sides of the flexible substrate, respectively, and since the conductive plugs are electrically connected with the bumps directly, when the chip is electrically connected to the conductive plugs through the bumps in the present invention, the temperature of the bumps may be quickly raised to a desirable level suitable for hot pressing. Therefore, the flexible substrate may not get damaged, and the chip may be quickly and reliably electrically connected to the inner leads.

Additionally, since only a plurality of bumps exists between the chip and the flexible substrate of the present invention, the liquid encapsulant may be fully filled in the gap between the chip and the flexible substrate when the encapsulant is formed.

It will be apparent to those skilled in the art that various modifications and variations can be made to the structure of the present invention without departing from the scope or spirit of the present invention. In view of the foregoing, it is intended that the present invention cover modifications and variations of this invention provided they fall within the scope of the following claims and their equivalents.

What is claimed is:

1. A chip package, comprising:
a flexible substrate, having a first surface and a second surface opposite to the first surface;
a plurality of conductive plugs, passing through the flexible substrate;
a wiring layer, located on the first surface, wherein the wiring layer has a plurality of inner leads electrically connected to the conductive plugs, respectively; and
a chip, having an active surface and a plurality of bumps disposed on the active surface, wherein the chip is disposed on the second surface of the flexible substrate and is bonded to the conductive plugs through the bumps.

2. The chip package as claimed in claim 1, wherein the wiring layer further comprises a plurality of traces and a plurality of outer leads, and the traces are connected between the inner leads and the outer leads.

3. The chip package as claimed in claim 1, further comprising an anisotropic conductive paste (ACP) disposed between the flexible substrate and the chip, such that the bumps are electrically connected to the conductive plugs.

4. The chip package as claimed in claim 1, further comprising an anisotropic conductive film (ACF) disposed between the flexible substrate and the chip such that the bumps are electrically connected to the conductive plugs.

5. The chip package as claimed in claim 1, further comprising a B stage adhesive disposed between the flexible substrate and the chip such that the bumps are electrically connected to the conductive plugs.

6. The chip package as claimed in claim 1, wherein the bumps comprise B stage conductive bumps.

7. The chip package as claimed in claim 1, further comprising a conductive paste or metal disposed between the bumps and the conductive plugs, through which the bumps are electrically connected to the conductive plugs.

8. The chip package as claimed in claim 1, further comprising a nonconductive polymer disposed between the flexible substrate and the chip, wherein the bumps are electrically connected to the conductive plugs.

9. The chip package as claimed in claim 1, further comprising an underfill disposed between the flexible substrate and the chip to encapsulate the bumps.

10. The chip package as claimed in claim 1, wherein the conductive plugs further protrude from the second surface.

11. The chip package as claimed in claim 1, further comprising an encapsulant disposed on the second surface to encapsulate the chip.

12. The chip package as claimed in claim 1, wherein the flexible substrate comprises polymer.

13. The chip package as claimed in claim 1, wherein the flexible substrate comprises polyimide.

14. A chip package, comprising:
a flexible substrate, having a first surface and a second surface opposite to the first surface;
a plurality of conductive plugs, passing through the flexible substrate;
a wiring layer, located on the first surface and electrically connected to the conductive plugs; and
a chip, having an active surface and a plurality of bumps disposed on the active surface, wherein the chip is disposed on the second surface of the flexible substrate and is electrically connected to the conductive plugs through the bumps, respectively, such that the bumps overlap with the conductive plugs.

15. The chip package as claimed in claim 14, wherein the bumps fully or partially overlap the conductive plug, respectively.

16. The chip package as claimed in claim 14, further comprising an anisotropic conductive paste (ACP) disposed between the flexible substrate and the chip, such that the bumps are electrically connected to the conductive plugs.

17. The chip package as claimed in claim 14, further comprising an anisotropic conductive film (ACF) disposed between the flexible substrate and the chip, such that the bumps are electrically connected to the conductive plugs.

18. The chip package as claimed in claim 14, wherein the bumps comprise B stage conductive bumps.

19. The chip package as claimed in claim 14, further comprising a conductive paste or metal disposed between the bumps and the conductive plugs, through which the bumps are electrically connected to the conductive plugs.

20. The chip package as claimed in claim 14, further comprising a nonconductive polymer disposed between the flexible substrate and the chip, wherein the bumps are electrically connected to the conductive plugs.
